(19) United States
(12) Patent Application Publication
(10) Pub. No.: US 2025/0309303 A1
(43) Pub. Date: Oct. 2, 2025

(54) MANUFACTURING DEVICE OF LAMINATED STRUCTURE BODY AND METHOD THEREOF

(71) Applicant: HONDA MOTOR CO., LTD., Tokyo (JP)

(72) Inventors: Yusuke WADA, Wako-shi (JP); Satoru NISHIGUCHI, Wako-shi (JP)

(21) Appl. No.: 19/062,956

(22) Filed: Feb. 25, 2025

(30) Foreign Application Priority Data
Mar. 27, 2024 (JP) 2024-050979

(51) Int. Cl. H01M 8/1004

(52) U.S. Cl. CPC H01M 8/1004

(57) ABSTRACT

A manufacturing device of a laminated structure body has: a pair of crimping members disposed to face with each other; a cushion material having flexibility and conductivity on a portion of at least one crimping member of the pair of crimping members facing the other crimping member; a crimping device to hold, press, and crimp a plurality of laminated sheet-shaped members between the one crimping member and the other crimping member so as to constitute a laminated structure body; and, a short-circuit inspection circuit that detects presence or absence of a short-circuit spot in the laminated structure body during a process where the crimping device crimps the plurality of sheet-shaped members in one piece to constitute the laminated structure body.

### CROSS-REFERENCE TO RELATED APPLICATION

The present application claims the benefit of priority to Japanese Patent Application No. 2024-050979 filed on Mar. 27, 2024, the disclosures of all of which are hereby incorporated by reference in their entireties.

### TECHNICAL FIELD

The present invention relates to a manufacturing device of a laminated structure body such as a membrane electrode structure body that constitutes a fuel cell, and a manufacturing method thereof.

### RELATED ART

Conventionally, a method with use of thermal compression has been widely used to manufacture a membrane electrode structure body that constitutes a fuel cell, as disclosed in JP Patent No. 6442544.

Further, when a membrane electrode structure body is manufactured, a method has been used to inspect whether an insulation is kept between an anode electrode and a cathode electrode (short-circuit inspection), as disclosed in JP Patent Application Publication No. 2023-40519.

In the conventional manufacturing method of a laminated structure body such as a membrane electrode structure body, a manufacturing device and an inspection device are provided separately so that a manufacturing process and an inspection process are performed separately. Therefore, manufacturing time or man-hours cannot be reduced.

The present invention is intended to solve the problem above and to provide a manufacturing device of a laminated structure body and a manufacturing method thereof which can reduce manufacturing time and costs, by performing a short-circuit inspection of an electrolyte membrane together when a membrane electrode structure body is manufactured.

### SUMMARY

To solve the problems above, a manufacturing device of a laminated structure body according to the present invention has: a pair of crimping members disposed to face with each other; a cushion material having flexibility and conductivity on a portion of at least one crimping member of the pair of crimping members facing the other crimping member; a crimping device to hold, press, and crimp a plurality of laminated sheet-shaped members between the one crimping member and the other crimping member so as to constitute a laminated structure body; and, a short-circuit inspection circuit that detects presence or absence of a short-circuit spot in the laminated structure body during a process where the crimping device crimps the plurality of sheet-shaped members in one piece to constitute the laminated structure body.

### Advantageous Effects of the Invention

According to the present invention, when a membrane electrode structure body is manufactured, a short-circuit inspection for an electrolyte membrane is performed together, which reduces manufacturing time and costs.

### BRIEF DESCRIPTION OF THE DRAWINGS

FIG. 1 is an exploded perspective view showing a configuration of a membrane electrode structure body;

FIG. 2 is a schematic diagram of main parts showing a manufacturing device of a laminated structure body according to a present embodiment;

FIG. 3 is a perspective view of the main parts showing the manufacturing device of a laminated structure body according to the present embodiment;

FIG. 4 is a schematic diagram of the main parts showing the manufacturing device of a laminated structure body according to a first modification;

FIG. 5 is a schematic diagram of the main parts showing the manufacturing device of a laminated structure body according to a second modification;

FIG. 6 is a perspective view of the main parts showing the manufacturing device of a laminated structure body according to the second modification; and

FIG. 7 is a schematic diagram of the main parts showing the manufacturing device of a laminated structure body according to a third modification.

### DETAILED DESCRIPTION

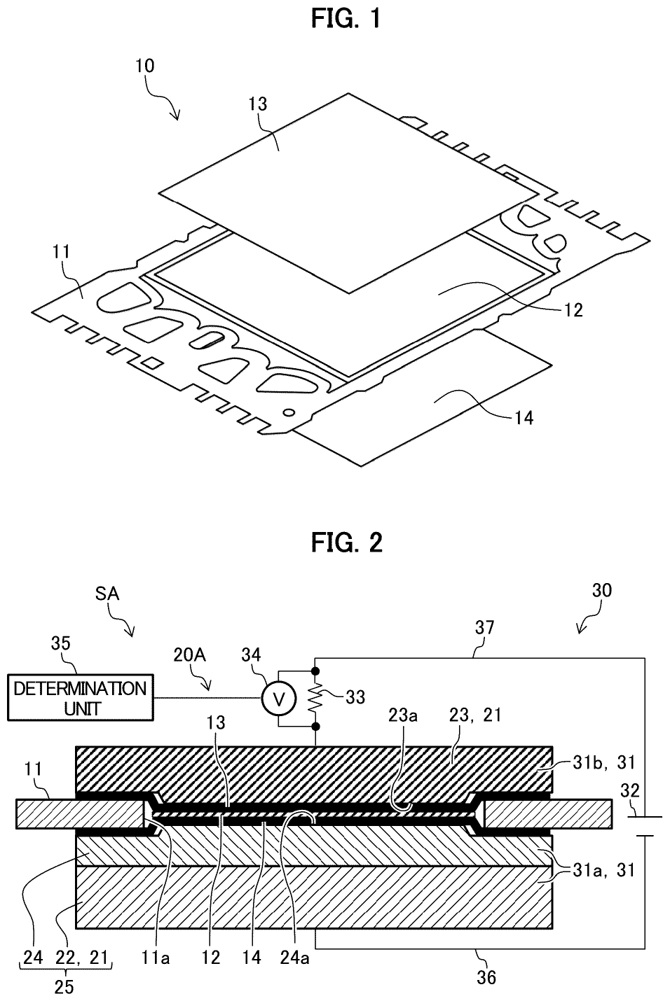

A description will be given of a manufacturing device SA of a laminated structure body according to one embodiment of the present invention in detail with reference to FIGS. 1 to 3.

Note that, in the description, the same element is denoted by the same symbol, and redundant descriptions are omitted.

Further, in the following description, “above” and “below” shall refer to “above” and “below” in a vertical direction of the manufacturing device, unless otherwise specified.

Prior to the description of the manufacturing device SA, a description will be given of a structure of a membrane electrode structure body 10 as a laminated structure body (see FIG. 1).

The membrane electrode structure body 10 constitutes a cell (not shown) as a power generator of a fuel cell (not shown), together with a pair of separators (not shown).

Further, the membrane electrode structure body 10 is held between the pair of separators, with an outer edge thereof supported by a frame member 11.

The membrane electrode structure body 10 (laminated structure body) has the frame member 11, a polymer electrolyte membrane 12, an anode electrode 13, and a cathode electrode 14.

The frame member 11 is made of a sheet-shaped resin material and has a rectangular frame shape with a rectangular hole 11a opening at a center portion thereof.

The polymer electrolyte membrane 12 is made of a sheet-shaped cation-exchanger membrane and is accommodated in the rectangular hole 11a of the frame member 11.

Then, the polymer electrolyte membrane 12 and the frame member 11 are held between the anode electrode 13 and the cathode electrode 14 to be tightly adhered and joined with each other.

In other words, the anode electrode 13 constitutes one of a pair of electrodes, and the cathode electrode 14 constitutes the other of the pair of electrodes.

Further, the anode electrode 13 is made of a sheet-shaped material and has a rectangular shape that is smaller than an outer shape of the frame member 11 and larger than the rectangular hole 11a.

Then, the anode electrode 13 is tightly adhered and joined to the polymer electrolyte membrane 12 and one surface of the frame member 11.

The anode electrode 13 is tightly adhered and joined to the polymer electrolyte membrane 12 at a center portion thereof and is tightly adhered and joined to the frame portion of the frame member 11 at a peripheral portion thereof.

In addition, the cathode electrode 14 is made of a sheet-shaped material and has a rectangular shape that is smaller than the outer shape of the frame member 11 and larger than the rectangular hole 11a.

Then, the cathode electrode 14 is tightly adhered and joined to the polymer electrolyte membrane 12 and the other surface of the frame member 11.

The cathode electrode 14 is tightly adhered and joined to the polymer electrolyte membrane 12 at a center portion thereof and is tightly adhered and joined to the frame portion of the frame member 11 at a peripheral portion thereof.

In other words, the membrane electrode structure body 10 (laminated structure body) includes a plurality of laminated sheet-shaped members to be tightly adhered and joined with each other to form a single member.

Note that, for convenience of description, a member in which each of the sheet members above laminated with each other is referred to as a laminated body, and a member in which each of the sheet members of the laminated body is joined in one member is referred to as a membrane electrode structure body 10.

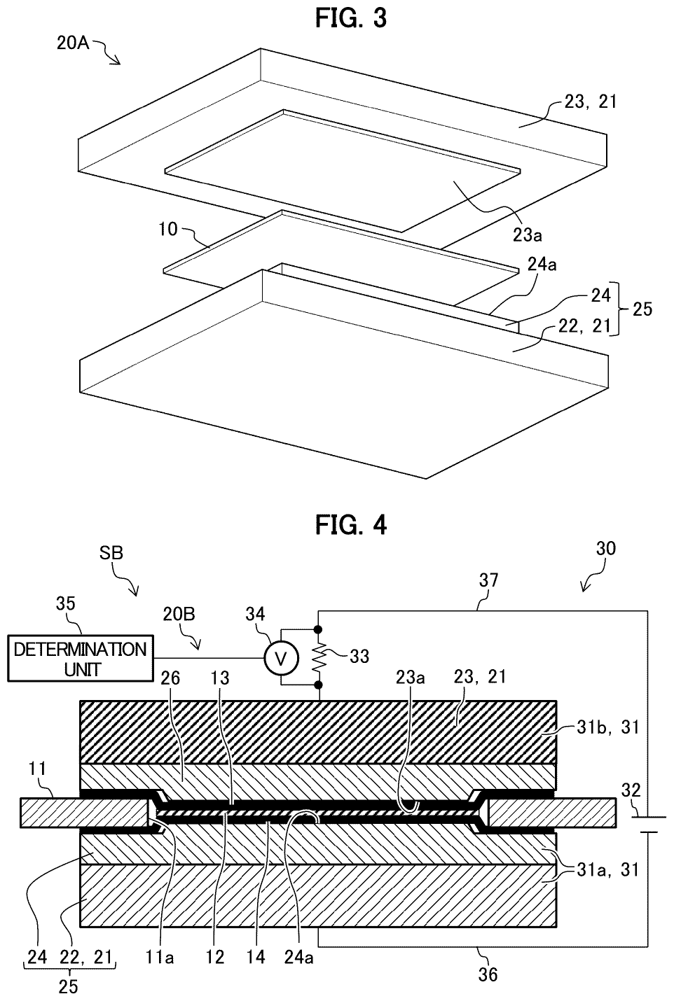

Next, a description will be given of the manufacturing device SA of the laminated structure body according to the present embodiment (see FIGS. 2 and 3).

When the membrane electrode structure body 10 above is manufactured, the manufacturing device SA of the laminated structure body performs tight adhesion, joining, and a short-circuit inspection of the frame member 11, the polymer electrolyte membrane 12, the anode electrode 13, and the cathode electrode 14.

For this purpose, the manufacturing device SA of the present embodiment has a crimping device 20A and a short-circuit inspection circuit 30.

The crimping device 20A includes a normal temperature crimping member 22 (one of crimping members) and a heat crimping member 23 (the other of crimping members).

Then, the normal temperature crimping member 22 and the heat crimping member 23 constitutes a pair of crimping members 21.

Further, the normal temperature crimping member 22 and the heat crimping member 23 are positioned to face so as to be close with and away from each other.

The normal temperature crimping member 22 is made of a flat-shaped conductive metal material.

The normal temperature crimping member 22 is fixed to the manufacturing device SA of a laminated structure body, with plate surfaces facing in the vertical direction.

The normal temperature crimping member 22 has a cushion material 24 on the plate surface facing the heat crimping member 23.

The cushion material 24 is made of a flat-shaped conductive elastic material, such as a conductive silicone rubber, for example.

The cushion material 24 is formed to have a dimension slightly larger than an outer dimension of the cathode electrode 14.

The cushion material 24 has a plate surface facing the heat crimping member 23 as a crimping surface (normal temperature-side crimping surface 24a).

Then, an assembly 25 made of the cushion material 24 and the normal temperature crimping member 22 constitutes a one-side electrode 31a below.

The heat crimping member 23 is made of a flat-shaped conductive metal material.

The heat crimping member 23 is heated so as to be held at a predetermined temperature.

The heat crimping member 23 is disposed to face the normal temperature crimping member 22 to be close to and away from the normal temperature crimping member 22, with the state that the plate surface of the heat crimping member 23 facing the normal temperature crimping member 22.

The heat crimping member 23 has a plate surface facing the normal temperature crimping member 22 as a crimping surface (heat-side crimping surface 23a).

Further, the heat crimping member 23 forms the other-side electrode 31b to be described below.

In other words, the pair of crimping members 21 are arranged facing each other to be close to and away from each other.

Then, the laminated body is placed between the normal temperature-side crimping surface 24a of the cushion material 24 and the heat-side crimping surface 23a of the heat crimping member 23, and the pair of crimping members 21 come close with each other to crimp the laminated body in one member so that the membrane electrode structure body 10 is formed.

The short-circuit inspection circuit 30 has a pair of electrodes 31, an inspection power supply 32, a shunt resistor 33, a voltmeter 34, and a determination unit 35.

The pair of electrodes 31 is made of the one-side electrode 31a and the other-side electrode 31b.

The one-side electrode 31a is made of the assembly 25 (normal temperature crimping member 22 and the cushion material 24).

Further, the one-side electrode 31a is electrically connected to a negative electrode of the inspection power supply 32 via a one-side wiring 36.

The other-side electrode 31b is made of the heat crimping member 23.

Further, the other-side electrode 31b is electrically connected to a positive electrode of the inspection power supply 32 via the other-side wiring 37.

Then, the other-side wiring 37 is connected to the shunt resistor 33.

In addition, the other-side wiring 37 is connected to the voltmeter 34 for measuring voltage drop at both ends of the shunt resistor 33.

The determination unit 35 calculates current value of current flowing through the shunt resistor 33 based on resistance value of the shunt resistor 33 and voltage value measured by the voltmeter 34.

The determination unit 35 then determines whether the membrane electrode structure body 10 has a short-circuit spot based on the calculated current value.

Next, a description will be given of operations of the manufacturing device SA of a laminated structure body.

First, the heat crimping member 23 is heated to keep at predetermined temperature, and is held apart from the normal temperature crimping member 22.

Next, each sheet-shaped material is placed on the normal temperature crimping member 22 to form the laminated body.

Then, the heat crimping member 23 is set down on the normal temperature crimping member 22 to hold the laminated body, and then, to press the laminated body at a predetermined pressure.

When pressing, the heat crimping member 23 heats the laminated body, which causes the electrodes and the polymer electrolyte membrane 12 to have adhesion and thermal plasticity.

The adhesion and pressure make each member of the laminated body in one piece to form the membrane electrode structure body 10.

Further, in a state that the laminated structure is being pressed, the determination unit 35 conducts electricity to the short-circuit inspection circuit 30 and measures the current flowing through the shunt resistor 33.

Then, the determination unit 35 determines presence or absence of a short-circuit based on the measured current value.

After the determination, the heat crimping member 23 is separated from the membrane electrode structure body 10, causing the temperature of the membrane electrode structure body 10 to fall down to normal temperature. Then, the adhesion and thermal plasticity are lowered and the membrane electrode structure body 10 is hardened.

Next, a description will be given of advantageous effects of the present embodiment.

The manufacturing device SA of the present embodiment includes the cushion material 24 made of conductive silicone rubber, having flexibility and conductivity, on the plate surface of the normal temperature crimping member 22, facing the heat crimping member 23.

The manufacturing device SA is configured such that a process of crimping the laminated body in one piece to form the membrane electrode structure body 10 is performed, together with a process of short-circuit inspection of the membrane electrode structure body 10.

This allows the manufacturing process and the inspection process of the membrane electrode structure body 10 to be performed in a single device, which reduces the manufacturing time and the manufacturing costs.

In contrast, in the conventional manufacturing method of the membrane electrode structure body 10, the manufacturing device and the inspection device are provided separately.

In a case where the manufacturing device and the inspection device are provided separately, the entire device becomes large so that a larger site area is necessary, which hinders cost reduction.

Further, in the case above, processes such as winding the membrane electrode structure body, transporting, and unwinding the wound membrane electrode structure body are required between the manufacturing and inspection processes.

During these processes, wrinkles and delamination may occur on the membrane electrode structure body, resulting in quality degradation and yield deterioration.

Further, in a case where the short-circuit is caused by a defect in a crimping member or the manufacturing device, when the manufacturing process and the inspection process are performed separately, there is a risk that the membrane electrode structure body may be short-circuited in all lots after the defect occurred.

In contrast, as in the present embodiment, in a case where a short-circuit is detected while the laminated structure is manufactured, as soon as the short-circuit is detected, a manufacturing line can be stopped immediately so that the cause can be inspected, which further reduces yield loss.

Note that the manufacturing device SA of the present embodiment is configured to press the laminated body while the heat crimping member 23 is heated at predetermined temperature, but the configuration is not limited thereto.

For example, if materials having an adhesive property at room temperature or adhering with each other are used, joining can be done by pressure alone without heating, which provides the same advantageous effects as in the above embodiment.

Further, in the present embodiment, one of the pair of electrodes is set as the anode electrode 13 and the other is set as the cathode electrode 14, but the configuration is not limited thereto.

For example, one of the electrodes may be a cathode electrode and the other may be an anode electrode, which provides the same advantageous effects.

Still further, in the manufacturing device SA of a laminated structure body of the present embodiment, a membrane electrode structure body 10 is illustrated as a laminated structure body, but is not limited thereto.

The manufacturing device SA may crimp the laminated body, which is formed with the laminated sheet-shaped members, in one member to form the laminated structure body. This provides the same advantageous effects.

Yet further, in the manufacturing device SA of a laminated structure body of the present embodiment, the heat crimping member 23 is configured to be movable, but is not limited thereto.

For example, the heat crimping member 23 may be fixed and the normal temperature crimping member 22 may be movable. This provides the same advantageous effects.

In the manufacturing device SA of the present embodiment, the cushion material 24 is made of conductive silicone rubber.

The configuration described above ensures sufficient conductivity even when a surface of the cushion material 24 is cracked due to aging.

This allows replacement of the cushion material 24 and maintenance intervals to be extended so that manufacturing costs are further reduced.

Note that, in the manufacturing device SA of the present embodiment, the cushion material 24 is made of conductive silicone rubber, but is not limited thereto.

For example, a metal foil may be adhered to a surface of a rubber material to use the metal foil as an electrode. This provides the same advantageous effects.

The manufacturing device SA of the present embodiment includes the short-circuit inspection circuit 30 equipped with the determination unit 35.

The configuration described above allows for determining presence or absence of a short-circuit in accordance with electrical characteristics of the membrane electrode structure body.

For example, in a case where the membrane electrode structure body 10 has dielectric properties, even if there is no short-circuit, current temporarily flows through the short-circuit inspection circuit 30 immediately after energization, and the current decreases as time passes.

Such transient response characteristics can be taken into account by the determination unit 35 so that determination can be done correctly.

Next, a description will be given of a first modification in detail with reference to FIG. 4.

The manufacturing device SB of the present modification differs from the aforementioned embodiment in that the cushion material 23 forming a heat crimping device 20B is also provided with a cushion material (heat-side cushion material 26).

The configuration as above allows for applying pressure more gradually to the laminated body when pressure is applied.

This can further reduce occurrence of creases or tears during crimping.

Note that the configuration of the present modification is suitable when thermal degradation of the cushion material 24 is small, such as when a set temperature of the heat crimping member 23 is closer to normal temperature and when heating is not required during crimping.

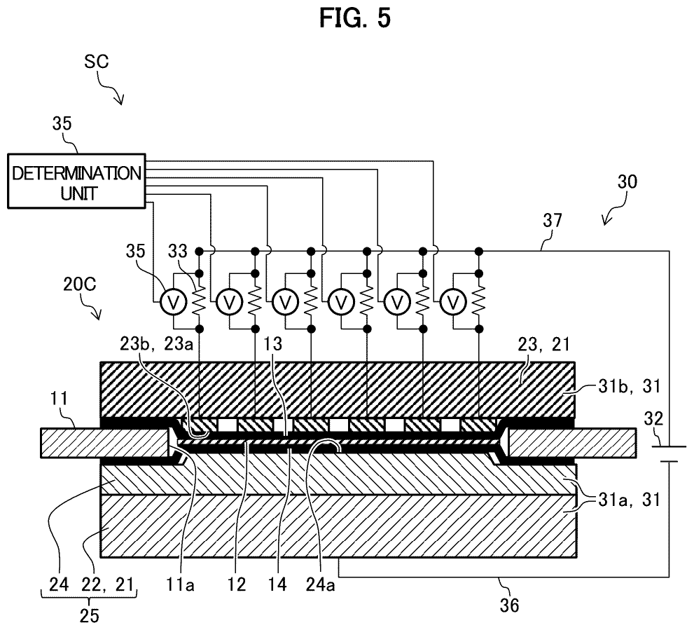

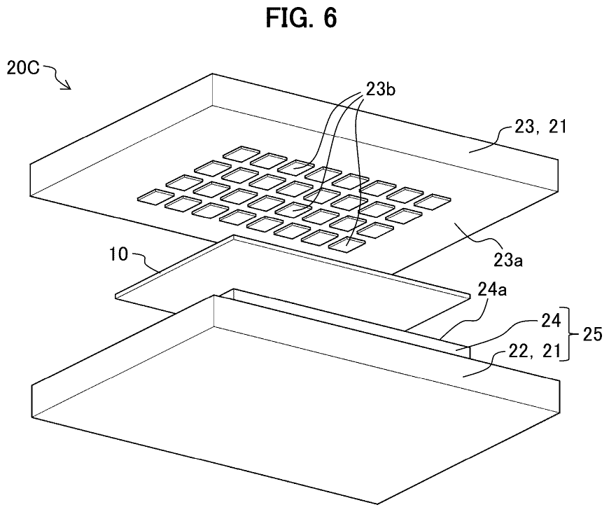

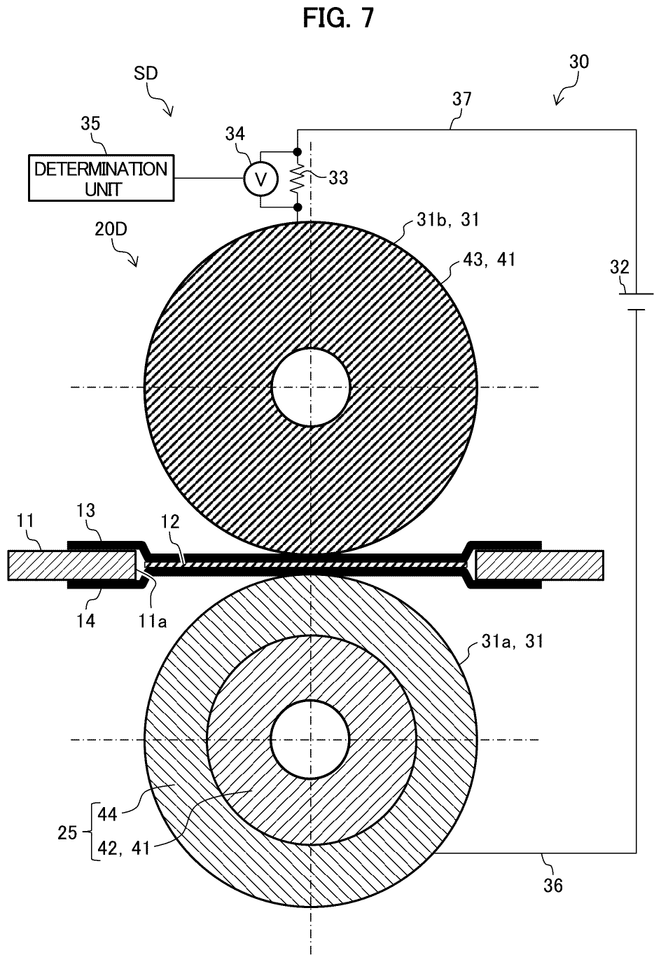

A description will be given of a second modification in detail with reference to FIGS. 5 and 6.

A manufacturing device SC of the present modification differs from the aforementioned embodiments in that the heat-side crimping surface 23a of the heat crimping member 23 forming a crimping device 20C is electrically divided into a plurality of regions 23b in a matrix-shape.

The configuration mentioned above allows for detecting presence or absence of a short-circuit in each regions 23b so that a spot of the short-circuit can be identified when the short-circuit is found in the membrane electrode structure body 10.

This allows for identifying a defective spot immediately when the short-circuit is caused by a defect in the crimping member.

Note that, in the present modification, a gap is formed between the regions 23b in a matrix shape to secure insulation between electrodes, but is not limited to the configuration described above.

For example, an insulator may be interposed between the electrodes in a matrix shape, and the heat-side crimping surface 23a of the heat crimping member 23 may be formed as a flat surface.

The configuration described above further reduces creases or tears that occur during crimping.

Further, in the present modification, the heat-side crimping surface 23a is divided into a matrix-shape, but is not limited to the configuration above.

For example, the heat-side crimping surface 23a may not be divided, but a normal temperature-side crimping surface 24a of the cushion material 24 may be divided into a matrix-shape configured to detect a short-circuit in each region, which provides the same advantageous effects.

Next, a description will be given of a third modification in detail with reference to FIG. 7.

A manufacturing device SC of the present modification differs from the aforementioned embodiments in that a crimping device 20D is made of rollers 41.

In other words, the normal temperature crimping member is made of a normal temperature roller 42, and the heat crimping member is made of a heat roller 43.

Then, a cushion material 44 is wound around an outer circumference of the normal temperature roller 42.

The cushion material 44 is made of a conductive elastic material such as conductive silicone rubber, for example.

This configuration described above performs inspection of a short-circuit in a straight region so that, when the short-circuit is found in the membrane electrode structure body 10, a spot of the short-circuit can be easily identified.

This allows for identifying the spot of the defect immediately when the short-circuit is caused by the defect in the crimping member.

Further, heating and crimping are performed with use of the rollers 41 so that the heat applied to the membrane electrode structure body 10 is reduced, which reduces thermal degradation of the cushion material 24.

What is claimed is:

1. A manufacturing device of a laminated structure body comprising:
a pair of crimping members disposed to face with each other;
a cushion material having flexibility and conductivity on a portion of at least one crimping member of the pair of crimping members facing the other crimping member;
a crimping device to hold, press, and crimp a plurality of laminated sheet-shaped members between the one crimping member and the other crimping member so as to constitute a laminated structure body; and,
a short-circuit inspection circuit that detects presence or absence of a short-circuit spot in the laminated structure body during a process where the crimping device crimps the plurality of sheet-shaped members in one piece to constitute the laminated structure body.

2. The manufacturing device of a laminated structure body according to claim 1, wherein the cushion material is made of conductive silicon rubber.

3. The manufacturing device of a laminated structure body according to claim 1, wherein the short-circuit inspection circuit includes a determination unit to determine presence or absence of a short-circuit of the laminated structure body.

4. The manufacturing device of a laminated structure body according to claim 1, wherein
at least the other crimping member is electrically divided into a plurality of regions, and
the short-circuit inspection circuit inspects presence or absence of the short-circuit per region.

5. A manufacturing method of a laminated structure comprising steps of:
crimping in which a laminated structure body is held and pressed between a pair of crimping members to crimp in one piece, and
after the laminated structure is crimped in one piece, inspecting in which current flowing through the laminated structure is detected to determine presence or absence of a short-circuit spot while the laminated structure is kept to be held and pressed.
